(19) United States
(12) Patent Application Publication
(10) Pub. No.: US 2024/0170282 A1
(43) Pub. Date: May 23, 2024

(54) METHOD AND SYSTEM FOR TUNING PHOTORESIST ADHESION LAYER PROPERTIES

(71) Applicant: ASM IP Holding B.V., Almere (NL)

(72) Inventors: Jerome Samuel Nicolas, Tokyo (JP); Fanyong Ran, Tokyo (JP); João Ricardo Antunes Afonso, Tokyo (JP); Yiting Sun, Leuven (BE)

(21) Appl. No.: 18/384,448

(22) Filed: Oct. 27, 2023

Related U.S. Application Data
(60) Provisional application No. 63/421,273, filed on Nov. 1, 2022.

(51) Int. Cl. H01L 21/02; C23C 16/455; H01L 21/027

(52) U.S. Cl. CPC H01L 21/02304; C23C 16/45544; H01L 21/0214; H01L 21/02164; H01L 21/02211; H01L 21/02216; H01L 21/02274; H01L 21/0228; H01L 21/0271

(57) ABSTRACT

Methods of forming structures including a photoresist underlayer and an adhesion layer and structures including the photoresist underlayer and adhesion layer are disclosed. Exemplary methods include forming the photoresist underlayer and forming an adhesion layer using a cyclical deposition process. The adhesion layer can be formed within the same reaction chamber used to form the photoresist underlayer. Properties of the adhesion layer can be tuned based on a selected photoresist by varying one or more process conditions.

### CROSS-REFERENCE TO RELATED APPLICATIONS

This application claims priority to U.S. Provisional Patent Application Ser. No. 63/421,273 filed Nov. 1, 2022 titled METHOD AND SYSTEM FOR TUNING PHOTORESIST ADHESION LAYER PROPERTIES, the disclosure of which is hereby incorporated by reference in its entirety.

### FIELD OF INVENTION

The present disclosure generally relates to methods of forming structures using photoresist patterning techniques. More particularly, the disclosure relates to methods of forming structures that include or are formed using a photoresist underlayer and to structures formed using such methods.

### BACKGROUND OF THE DISCLOSURE

During the manufacture of electronic devices, fine patterns of features can be formed on a surface of a substrate by patterning the surface of the substrate and etching material from the substrate surface using, for example, gas-phase etching processes. As a density of devices on a substrate increases, it becomes increasingly desirable to form features with smaller dimensions.

Photoresist is often used to pattern a surface of a substrate prior to etching. A pattern can be formed in the photoresist, by applying a layer of photoresist to a surface of the substrate, masking the surface of the photoresist, exposing the unmasked portions of the photoresist to radiation, such as ultraviolet light, and removing a portion (e.g., the unmasked or masked portion) of the photoresist, while leaving a portion of the photoresist on the substrate surface.

Recently, techniques have been developed to use extreme ultraviolet (EUV) wavelengths to develop patterns having relatively small pattern features (e.g., 10 nm or less). To form features on a substrate using EUV, a photoresist underlayer is often deposited onto a surface of a substrate, and then an EUV photoresist layer is deposited overlying the photoresist underlayer. The photoresist underlayer can facilitate etch selectivity between the photoresist and a hard mask material and promote adhesion of the photoresist to the hard mask material.

As critical dimensions of features formed during manufacture of electronic devices continue to decrease, it becomes increasingly desirable and challenging for the photoresist underlayer and the photoresist to exhibit desired adhesion. The adhesion between the photoresist underlayer and the photoresist can depend on a variety of factors, including the type and composition of the photoresist.

Various techniques to increase adhesion between photoresist and a photoresist underlayer include functionalizing a surface of the photoresist underlayer using primers or brushes. While these ex-situ techniques can work for some applications, such techniques can require additional steps, such as annealing or heating, and may be specific to a particular photoresist. Such techniques are generally not tunable for use with a variety of photoresists. Accordingly, improved methods for tuning properties of photoresist underlayers or adhesion layers thereon and structures formed using such methods are desired.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to methods of forming a structure comprising a photoresist underlayer. While the ways in which various embodiments of the present disclosure address drawbacks of prior methods and structures are discussed in more detail below, in general, various embodiments of the disclosure provide methods that include forming an adhesion layer overlying the photoresist underlayer. As set forth in more detail below, various process conditions during formation of the adhesion layer can be manipulated to tune properties of the adhesion layer to obtain desired adhesion between the photoresist and the photoresist underlayer.

In accordance with exemplary embodiments of the disclosure, a method of forming a structure comprising a photoresist underlayer is provided. An exemplary method includes providing a substrate within a reaction chamber, forming a photoresist underlayer (sometimes referred to herein simply as an underlayer) on a surface of the substrate, selecting a photoresist to deposit onto the adhesion layer, manipulating process conditions for use during the step of forming the adhesion layer to tune properties of the adhesion layer based on the selected photoresist, and forming an adhesion layer on a surface of the underlayer. The adhesion layer can be interposed between and in contact with both the photoresist underlayer and a photoresist layer. Examples of the disclosure can further include forming the (e.g., EUV) photoresist layer overlying the adhesion layer. The adhesion layer can be formed using a cyclic deposition process. The cyclical deposition process can include providing a silicon precursor to the reaction chamber, providing an oxygen-free (e.g., an inert reactant into the reaction chamber), and forming a plasma using the oxygen-free reactant to form activated species that react with the silicon precursor or a derivative thereof to form the adhesion layer. The photoresist underlayer can include one or more of silicon and a metal. For example, the photoresist underlayer can include one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride. When the photoresist underlayer comprises silicon, the same or a different silicon precursor can be used to form the photoresist underlayer and the adhesion layer.

In accordance with further examples, the photoresist underlayer can also be formed using a cyclic deposition process, such as a plasma-enhanced cyclic (e.g., atomic layer) deposition process or a thermal cyclic deposition process. The photoresist underlayer can have a thickness of less than 10 nm or less than 5 nm. The photoresist layer can be or include, for example, positive or negative tone extreme ultraviolet (EUV) lithography photoresist.

In accordance with yet additional exemplary embodiments of the disclosure, a structure that includes a photoresist underlayer and an adhesion layer is provided. The photoresist underlayer and/or adhesion layer can be formed using a method as described herein. The photoresist underlayer can include, for example, a layer comprising a metal and/or silicon. The adhesion layer can include silicon. The adhesion layer can have tuned surface energy properties as described herein. Exemplary structures can also include a layer of photoresist, such as negative tone or positive tone EUV photoresist.

In accordance with further examples of the disclosure, a system for forming an adhesion layer is provided. Exemplary systems include a reaction chamber, a silicon precursor source fluidly coupled to the reaction chamber, an inert gas source fluidly coupled to the reaction chamber, and a controller configured to perform a method as described herein or a portion thereof.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a method in accordance with exemplary embodiments of the disclosure.

FIG. 3 illustrates a structure in accordance with exemplary embodiments of the disclosure.

FIG. 4 illustrates a system configured for executing a method as described herein.

FIG. 5 illustrates an exemplary reactor system in accordance with yet additional examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses thereof and obvious modifications and equivalents thereof. Thus, it is intended that the scope of the invention disclosed should not be limited by the particular disclosed embodiments described below.

The present disclosure generally relates to methods of forming structures that include a photoresist underlayer and an adhesion layer and to structures including a photoresist underlayer and an adhesion layer. As described in more detail below, exemplary methods can be used to form structures with photoresist underlayers and adhesion layers with desired properties. More particularly, examples of the disclosure provide techniques for tuning desired properties of an adhesion layer to obtain desired adhesion between the underlayer and the photoresist. As set forth in more detail below, various properties of the adhesion layer, such as composition and surface free energy (SFE) can be tuned my manipulating one or more process parameters during the step of forming the adhesion layer.

As used herein, the term “substrate” may refer to any underlying material or materials including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can additionally or alternatively include various features, such as recesses, lines, and the like formed within or on at least a portion of a layer of the substrate.

In some embodiments, “film” refers to a layer extending in a direction perpendicular to a thickness direction. In some embodiments, “layer” refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, continuously or continuous or continually can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

In this disclosure, “gas” may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as a rare gas.

In some cases, such as in the context of deposition of material, the term “precursor” can refer to a compound that participates in the chemical reaction that produces another compound, and particularly to a compound that constitutes a film matrix or a main skeleton of a film, whereas the term “reactant” can refer to a compound, in some cases other than precursors, that activates a precursor, modifies a precursor, or catalyzes a reaction of a precursor; a reactant may provide an element (such as O, N, C) to a film matrix and become a part of the film matrix. In some cases, a reactant can include an otherwise inert gas that is activated—e.g., via a plasma. In some cases, the terms precursor and reactant can be used interchangeably. The term “inert gas” refers to a gas that does not take part in a chemical reaction to an appreciable extent and/or a gas that excites a precursor when, for example, RF or microwave power is applied, but unlike a reactant, it may not become a part of a film matrix to an appreciable extent.

The term “cyclic deposition process” or “cyclical deposition process” may refer to the sequential introduction of precursors (and/or reactants) into a reaction chamber and/or pulsing of plasma power to form excited species to deposit a layer over a substrate and includes processing techniques such as atomic layer deposition (ALD), cyclical chemical vapor deposition (cyclical CVD), hybrid cyclical deposition processes that include an ALD component and a cyclical CVD component, and plasma-enhanced versions thereof.

The term “atomic layer deposition” may refer to a vapor deposition process in which deposition cycles, typically a plurality of consecutive deposition cycles, are conducted in a process chamber. Generally, for ALD processes, during each cycle, a precursor is introduced to a reaction chamber and is chemisorbed on a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas or an inert gas) may subsequently be introduced into the process chamber for use in converting the chemisorbed precursor to the desired material on the deposition surface. The reactant/inert gas can be capable of further reaction or interaction with the precursor. Purging steps can be utilized during one or more cycles, e.g., during or after each step of each cycle, to remove any excess precursor from the process chamber and/or remove any excess reactant and/or reaction byproducts from the reaction chamber. Plasma-enhanced ALD can include use of a plasma to form activated species—e.g., from a reactant gas and/or an inert gas.

In this disclosure, any two numbers of a variable can constitute a workable range of the variable, and any ranges indicated can include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” and variations thereof can refer independently to “typically or broadly comprising,” “comprising,” “consisting essentially of,” or “consisting of” and variations thereof in some embodiments. In accordance with aspects of the disclosure, any defined meanings of terms do not necessarily exclude ordinary and customary meanings of the terms.

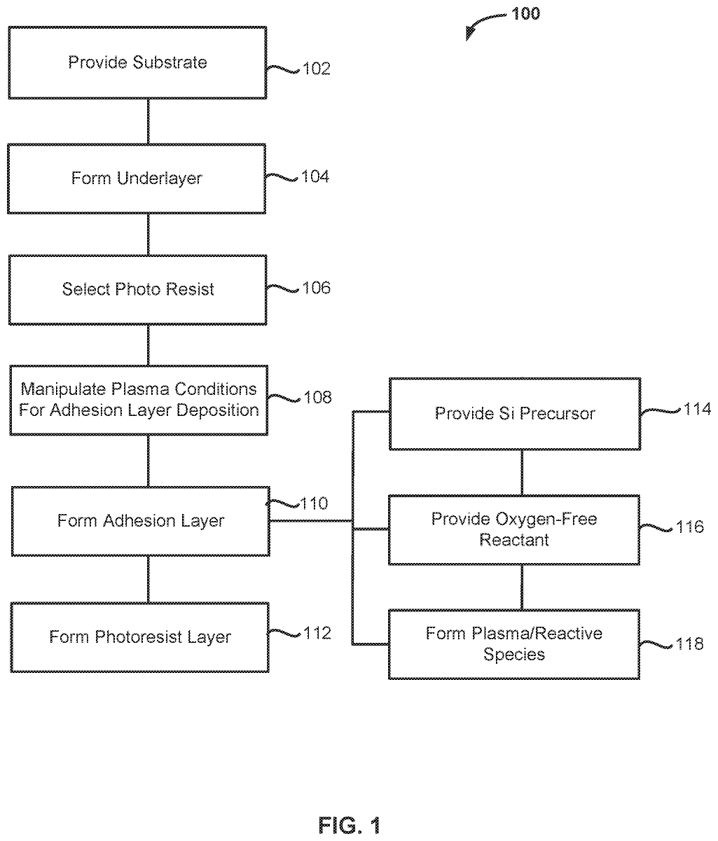

Turning now to the figures, FIG. 1 illustrates a method 100 in accordance with exemplary embodiments of the disclosure. Method 100 includes the steps of providing a substrate (step 102), forming a photoresist underlayer (step 104), selecting a photoresist to deposit onto the adhesion layer (step 106); manipulating process conditions for use during the step of forming the adhesion layer (step 108), forming an adhesion layer (step 110), and forming a photoresist layer (step 112).

Step 102 includes providing a substrate, such as a substrate described herein. The substrate can include one or more layers, including one or more material layers, to be etched. By way of examples, the substrate can include a deposited oxide, a native oxide, or an amorphous carbon layer to be etched. The substrate can include several layers underlying the material layer(s) to be etched.

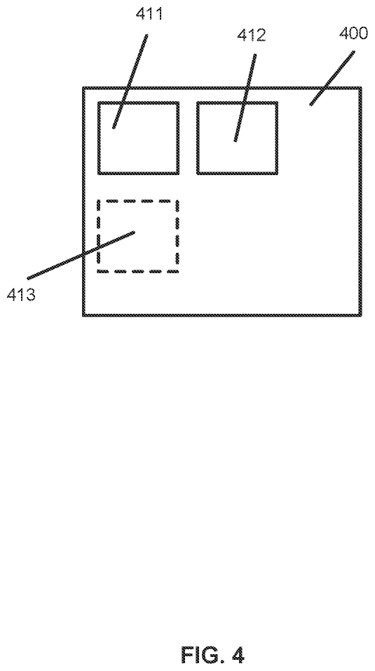

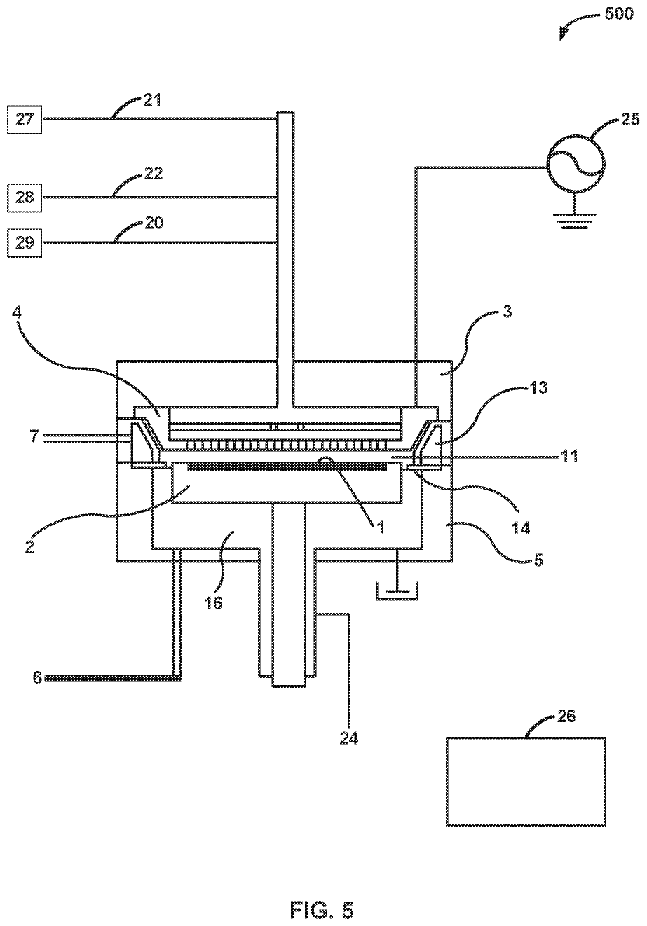

The substrate is provided within a reaction chamber. The reaction chamber can be, for example, a reaction chamber of a plasma-enhanced reactor system. Exemplary reaction chambers suitable for use with step 102 are described in more detail below in connection with FIGS. 4 and 5.

During step 104, a photoresist underlayer is formed on a surface of the substrate. The photoresist underlayer can be formed using a variety of techniques, including spin-on, chemical vapor deposition, and cyclical process techniques. Plasma deposition materials have been identified as promising candidates for photoresist underlayer material due to an ability to deposit relatively thin layers with relatively low thickness variation and lower dry etching rates of plasma-deposited material, compared with the conventional spin-on-glass (SoG).

In accordance with exemplary aspects of method 100, the photoresist underlayer is formed during step 104 using a cyclical deposition process, such as an ALD process—e.g., PEALD. The cyclical deposition process can include use of activated species (e.g., formed from one or more of precursor(s), reactant(s), or and/or inert gas(es)) that are formed using one or more of a direct plasma and a remote plasma. Alternatively, step 104 can include a thermal cyclical deposition process. Use of cyclical deposition processes may be desirable, because they allow for the formation of a photoresist underlayer with desired thickness—e.g., less than 10 nm or less than or about equal to 5 nm, with improved thickness uniformity-both within a substrate and from substrate-to-substrate. Using a plasma-enhanced process may be desirable, because plasma-enhanced processes allow for deposition of the photoresist underlayer material at relatively low temperatures and/or relatively high rates-compared to thermal processes.

In accordance with examples of the disclosure, a temperature within a reaction chamber during step 104 can be less than 500° C., less than 400° C., less than 300° C. or between about 50° C. and about 150° C., or about 150° C. and about 300° C. A pressure within the reaction chamber during step 104 can be about 1 Torr to about 100 Torr, about 3 Torr to about 50 Torr, or about 5 Torr to about 20 Torr.

In accordance with exemplary embodiments of the disclosure, step 104 includes forming or depositing one or more of a silicon or metal oxide, a silicon or metal nitride, and a silicon or metal oxynitride. Such oxides, nitrides, and/or oxynitrides can also include carbon.

The photoresist underlayer can include, for example, one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride. The metal can include, for example, one or more metals selected from the group consisting of titanium, tantalum, tungsten, tin, and hafnium. In some cases, the photoresist underlayer includes carbon. The carbon can be incorporated into the photoresist underlayer as the photoresist underlayer is deposited and/or a carbon treatment can be applied to a surface of the photoresist underlayer. Additionally or alternatively, a carbon-containing layer or other layer can be deposited onto a surface of the photoresist underlayer. A thickness of the photoresist underlayer can be less than 10 nm, less than 5 nm, or greater than 3 and less than 10 nm.

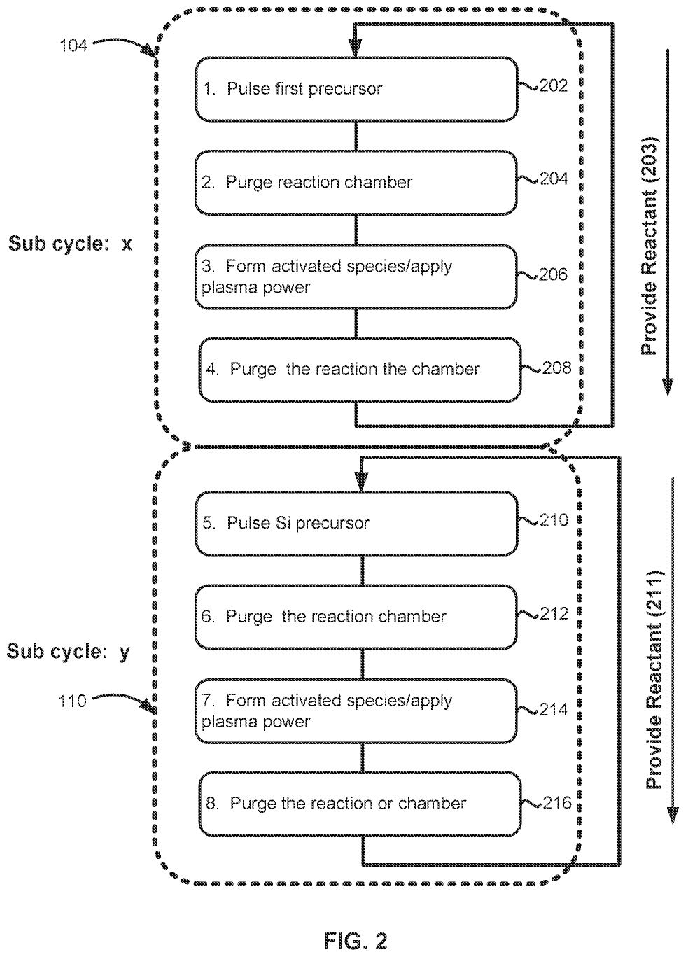

A cyclical process for forming the photoresist underlayer suitable for step 104 is illustrated in FIG. 2 (sub cycle x). Sub cycle x can include pulsing a first precursor comprising a metal or silicon into a reaction chamber (step 202), providing a reactant (step 203), and forming activate species—e.g., by providing (e.g., pulsing) a plasma power (step 206). Sub cycle x can also include one or more purge steps 204, 208. Sub cycle x can be repeated—e.g., between about 10 and about 50 or about 100 and about 200 times before method 100 proceeds to step 110.

Each purge step 204, 208 can be performed by, for example, supplying an inert gas and/or reactant (e.g., without plasma-activating the reactant) to the reaction chamber and/or using a vacuum source.

In some cases, the reactant can be continuously provided during one or more (e.g., all) of steps 202-208, as illustrated in FIG. 2.

In accordance with exemplary aspects of the disclosure, a first precursor comprising silicon is provided during step 202. In some cases, the silicon precursor can also include carbon. Exemplary silicon precursors suitable for use in forming a photoresist underlayer include a molecule comprising silicon, oxygen, carbon, and optionally nitrogen. The molecule can be represented by the formula: SiₐC_{b}O_{c}H_{d}Nₑ, where a is an integer from at least 1 to at most 2 or from 0 to at most 5, b is an integer from at least 0 or =5 to at most 14, c is an integer from at least 0 or 2 to at most 4, d is an integer from at least 0 or 12 to at most 30, and e is an integer from at least 0 to at most 2 or 4.

Exemplary silicon precursors can additionally include one or more of (i) one or two silicon-oxygen bonds, (ii) one or two silicon-carbon bonds, (iii) one carbon-carbon double bond, and/or (iv) a triple bond. In some cases, the molecule includes two silicon-oxygen bonds and two silicon-carbon bonds. In some cases, the molecule can include a silicon-nitrogen bond.

In accordance with further examples, the molecule comprises a backbone structure selected from the group consisting of:

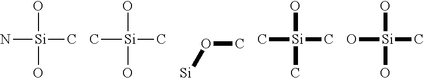

wherein each terminal group can be replaced with a group represented by the formula Si_{w}CₓO_{y}H_{z}N_{z1} where w, x, y, z and z1 can be 0 or greater, and where the molecular structure comprises single, double and/or triple bonds. By way of examples, w can range from 0 to 5, x can range from 0 to 14, y can range from 0 to 4, z can range from 0 to 30, and z1 can range from 0 to 4.

By way of particular examples, the silicon precursor can be or include one or more of N-[dimethoxy(propan-2-yl)silyl]-N-methylmethanamine, N-[ethyl(dimethoxy)silyl]-N-methylmethanamine, diisobutyldimethoxysilane, dimethoxydiethylsilane, dimethoxymethylvinylsilane, bis(methyldimethoxysilyl)methane, 1,2-bis(methyldiethoxysilyl)ethane, trimethoxy(3-methoxypropyl)silane, methyltrimethoxysilane, tetramethylcyclotetrasiloxane, polymethysilsesquioxane, diethoxy-methyl-silane, dimethyl-dioxiranyl-silane, diethoxy-methyl-oxiranyl-silane, trimethyl-trivinylcyclotrisiloxane, decamethyl-cyclopentasiloxane and diethoxy-methyl-silane, or the like.

In accordance with other exemplary aspects of the disclosure, the first precursor comprises a metal. In these cases, the first precursor can include a transition metal, such as one or more metals selected from the group consisting of titanium, tantalum, tungsten, tin, and hafnium. The first precursor comprising a metal can also include carbon—e.g., one or more organic groups bonded directly or indirectly to a metal atom. By way of particular examples, the first precursor comprising a metal can include a metal halide or a metal organic compound, or an organometallic compound, such as one or more of tetrakis(dimethylamino)titanium (TDMAT), titanium isopropoxide (TTIP), titanium chloride (TiCl), tetrakis(ethylmethylamino)hafnium (TEMAHf), hafnium chloride (HfCl), trimethylaluminum (TMA), triethylaluminium (TEA), other metal halide, or other metal-containing compounds.

The reactant can include an oxidizing reactant, a nitriding reactant, an inert gas, and/or a reducing agent, such as a hydrogen-containing reactant. The oxidizing and/or nitriding reactant can include reactants that include one or more of oxygen and nitrogen. In some cases, the reactant can include both nitrogen and oxygen. And, in some cases, the two or more oxidizing and/or nitriding reactant can be included in a single pulse. Exemplary oxidizing and nitriding agents include oxygen (O₂), water (H₂O), ozone (O₃), hydrogen peroxide (H₂O₂), ammonia (NH₃), diazene (N₂H₂), carbon dioxide (CO₂), nitrous oxide (N₂O); exemplary hydrogen-containing reactants include hydrogen (H₂), and the like. By way of particular example, the reactant can include a gas comprising an oxidant (e.g., O₂) and an inert gas, such as argon. Exemplary reactants can include, for example, about 10 to about 70 volumetric percent oxidant and/or about 30 to about 90 volumetric percent inert gas. The reactant can be exposed to a (e.g., direct) plasma during step 206 to form excited species for use in a plasma-assisted cyclical process, such as a PEALD process.

When used, the carbon precursor can include any suitable organic compound, such as compounds comprising carbon and oxygen. In some cases, the carbon precursor can also include nitrogen. The carbon precursor can be selected to react with, for example an —OH terminated surface of metal oxides and/or a —NH₂ terminated surface of a metal nitride. Examples of suitable carbon precursors include one or more of organic compounds, such as acid anhydrate (e.g., an acetic anhydrate), toluene, diethylene glycol, triethylene glycol, acetaldehyde, and organosilicon compounds, such as silanes, and siloxanes. Exemplary organosilicon compounds include (n,n-dimethylamino)trimethylsilane, trimethoxy(octadecyl)silane, hexamethyldisilazane, trimethoxy(3,3,3-trifluoropropyl)silane, trimethoxyphenylsilane, trichloro(3,3,3-trifluoropropyl)silane and hexamethyldisilazane.

During step 106, a photoresist to be deposited during step 112 is selected. The photoresist can be a positive or negative photoresist. By way of examples, the photoresist can be an extreme UV photoresist, such as an organic chemically amplified resist. Although step 106 is illustrated after step 104, step 106 can suitably be performed at any stage prior to step 110.

Once the photoresist is selected, process conditions for step 110 can be selected or manipulated to tune properties of the adhesion layer based on the selected photoresist. In accordance with examples of the disclosure, only process conditions are manipulated to account for various photoresists selected during step 106. In some cases, the precursor does not change. In some cases, the reactant does not change. Examples of process conditions/variables that can be manipulated are discussed in more detail below in connection with step 110.

With reference again to FIGS. 1 and 2, once the photoresist underlayer is formed, an adhesion layer is formed during step 110. Step 110 can be performed in situ-within the same reaction chamber used during steps 102, 104 and without an air and/or a vacuum break. In some cases, step 110 does not include providing a reactant comprising oxygen to the reaction chamber.

As illustrated in FIG. 1, step 110 can include the substeps of providing a silicon precursor (step 114), providing an oxygen-free reactant (step 116), and forming a plasma, or more generally, reactive species (step 118). Step 110 can include a cyclical deposition process, such as a plasma-enhanced cyclical deposition process (e.g., a PEALD process). For example, with reference to FIG. 2, step 110 can include pulsing a silicon precursor to a reaction chamber (step 210 (corresponding to step 114)), purging the reaction chamber (step 212), providing an oxygen-free reactant to the reaction chamber (step 211, corresponding to step 116), and forming activated species/a plasma (step 214, corresponding to step 118) using the oxygen-free reactant to form activated species (e.g., by forming a plasma using the oxygen-free reactant) that react with the silicon precursor or a derivative thereof to form the adhesion layer on the surface of the underlayer formed during step 104, and purging any excess reactive species and/or byproducts from the reaction chamber (step 216). As illustrated, sub cycle y can be repeated a number of times—e.g., between about 10 and about 50, between about 150 and about 200 or about 300 or about 400 or about 70 and about 120 times. The temperature and pressure during step 106 can be the same or similar for step 102 and/or 104. A thickness of the adhesion layer can be greater than 0 and less than 2 nm.

During step 210, a silicon precursor is provided (e.g., pulsed) to the reaction chamber. In accordance with examples of the disclosure, the silicon can be or include a silicon precursor as described above in connection with step 202. In some cases, the silicon precursor used during step 210 can be the same silicon precursor used during step 202. In some cases, the silicon used during step 210 does not comprise nitrogen. N-free precursors can be beneficial for use in forming an adhesion layer, because nitrogen is thought to exhibit a poisoning effect due to the presence of N atoms. In accordance with further examples, the silicon precursor consists of or consists essentially of Si, C, H, and O, which may be provided to the reaction chamber with the aid of a carrier gas (which can be or include an inert gas). Further, the oxygen-free reactant can be provided continuously during the step of forming the underlayer (step 104) and one or more cycles of forming an adhesion layer (step 110). Exemplary precursor pulse times, flowrates, and dilution for step 210/114 are provided below in Table 1.

During step 211/116, the oxygen-free reactant is provided to the reaction chamber. As illustrated, the oxygen-free reactant can be provided continuously during step 211 during one or more cycles of the cyclical deposition process. The oxygen-free gas can be or include one or more of argon, helium, neon, krypton, xenon, and hydrogen. A flowrate of the oxygen-free reactant can be between about 0.006 and about 6 slm; other suitable ranges are provided in Table 1.

During step 212, any excess silicon precursor and/or any reaction byproducts can be purged from the reaction chamber. The purge can be performed by supplying an inert gas and/or the reactant to the reaction chamber and/or using a vacuum source.

During step 214/118, a plasma can formed using an oxygen-free gas. A power to form the plasma can be about 30 W to about 1000 W or less than 150 W or between 10 and 150 W or between 10 and 400 W or between 10 and 1000 W—e.g., for a 300 diameter substrate and can be similarly scaled for substrates of other cross-sectional dimensions. A frequency of the power to form the plasma can be between about 200 kHz and about 2.45 GHz. A duration of step 214 can be less than 4 seconds or less than 2 seconds or between about 0.1 s and about 4 or between about 0.1 s and about 2 s.

During step 216, the reaction chamber can be purged—e.g., using the oxygen-free reactant. Sub cycle y can be repeated a number of times to form a silicon-based adhesion layer of a desired thickness—e.g., greater than 0 and less than about 2 nm.

As noted above, one or more process conditions can be varied to account for different photoresists to be deposited during step 112. By way of examples, the process conditions can be selected from one or more of reaction chamber temperature, reaction chamber pressure, gap between electrodes, precursor flowrate, reactant flowrate, precursor dilution, reactant dilution, precursor purge time, number of deposition cycles, plasma power, and plasma power duration. Examples of the range for each process condition are provided below. Unless otherwise noted, these examples are not meant to limit the scope of the invention, but are meant to illustrate examples of the disclosure. Further, the rages for each process condition can be combined in any combination.

TABLE 1

| | Exemplary | Exemplary | Exemplary |
|---|---|---|---|
| Process Condition | Range 1 | Range 2 | Range 3 |
| Temperature (° C.) | | | 5--500 |
| Pressure (Pa) | 200-800 | 100-2000 | 200-2000 |
| electrode gap (mm) | | 7-15 | 6-18 |
| Precursor flowrate (including | | 10-6000 | |
| carrier gas) (sccm) | | | |
| Precursor pulse time (seconds) | Greater than | 0.1-2 | 0.01-4 |
| | 0.01 | | |
| Reactant flowrate (sccm) | | 5-100 | 100-6000 |
| Precursor dilution (vol %) | | | |
| Reactant dilution (vol %) | | | |
| Precursor purge time (seconds) | | | 0.2-1 |
| Number of adhesion layer | 10-50 | 150-200 | 300-400 |
| deposition cycles | | | |
| plasma power (W) | 10-150 | 10-400 | 10-1000 |
| plasma power pulse time | Less than 4 | Less than 2 | 0.1-4 |
| (seconds) | | | |

Methods in accordance with the disclosure can also include a step of forming a photoresist layer overlying and in contact with the adhesion layer (step 112). The photoresist can be deposited using, for example, spin-on techniques. As noted above, photoresist layer can be or include positive or negative tone extreme ultraviolet (EUV) lithography photoresist.

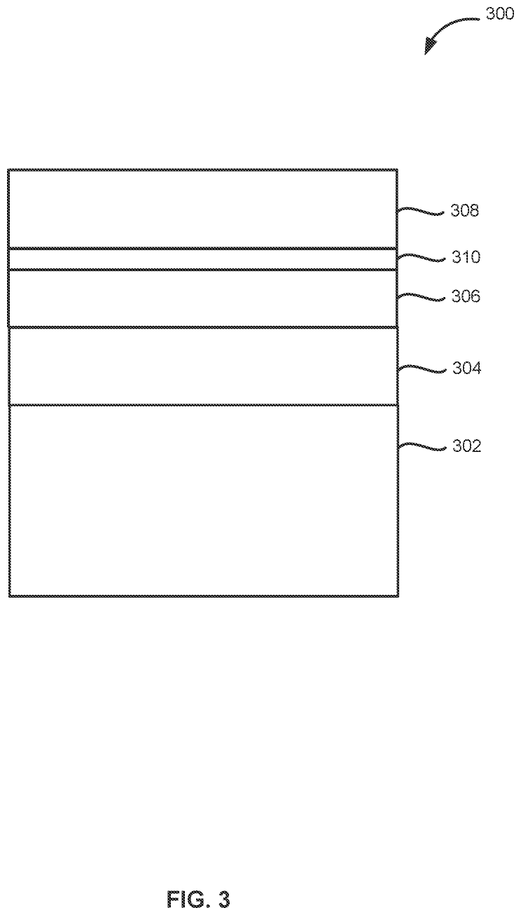

FIG. 3 illustrates a structure 300 in accordance with exemplary embodiments of the disclosure. Structure 300 can be formed using, for example, method 100 and/or 200.

As illustrated, structure 300 includes a substrate 302, a material layer 304, a photoresist underlayer 306, a photoresist layer 308, and an adhesion layer 310 interposed between and in contact with photoresist underlayer 306 and photoresist layer 308.

Substrate 302 can include a substrate as described above. By way of examples, substrate 302 can include a semiconductor substrate, such as a bulk material, such as silicon (e.g., single-crystal silicon), other Group IV semiconductor material, Group Ill-V semiconductor material, and/or Group II-VI semiconductor material and can include one or more layers (e.g., a patterning stack) overlying the bulk material. Further, as noted above, substrate 302 can include various topologies, such as recesses, lines, and the like formed within or on at least a portion of a layer of the substrate.

Material layer 304 can be patterned and etched using a photoresist underlayer and a layer of photoresist as described herein. Exemplary materials suitable for material layer 304 include, for example, oxides, such as native oxides or field oxides. Other exemplary material layer 304 materials include amorphous carbon, nitrides, other oxides, silicon, and add-on films (e.g., a self-assembled monolayer (e.g., hexamethyldisilazane (HMDS)).

Photoresist underlayer 306 can include a photoresist underlayer formed in accordance with a method described herein (e.g., method 100) and/or have properties and/or material as described herein. Exemplary photoresist underlayers include one or more of a silicon or metal oxide, a silicon or metal nitride, and a silicon or metal oxynitride-any of which can include or not include carbon. For example, photoresist underlayer 306 can include one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

A thickness of photoresist underlayer 306 can depend on a composition of material layer 304, a thickness of material layer 304, a type of photoresist, and the like. In accordance with examples of the disclosure, photoresist underlayer 306 has a thickness of less than 10 nm or less than or about 5 nm or between about 3 nm and about 10 nm. If photoresist underlayer 306 is too thick, residual underlayer material may remain after an etch step. If photoresist underlayer 306 is too thin, photoresist underlayer 306 may not provide desired pattern transfer during an etch process.

Adhesion layer 310 desirably exhibits good adhesion and other properties as described herein. In accordance with examples of the disclosure, adhesion layer 310 includes silicon and can optionally include one or more of carbon, hydrogen, and oxygen. As noted above, adhesion layer 310 may desirably not include nitrogen. In some cases, such as for CAR resist, adhesion layer 310 may desirably include a high carbon concentration, such as greater than 25, 30, 45, or greater than 50 at % carbon. or between 25 and 45 at % carbon.

To provide desired adhesion between photoresist layer 308 and photoresist underlayer 306, adhesion layer 310 may have or be tuned to have desired surface chemistry properties, e.g., quantified as surface energy, which is further categorized into a polar part of surface energy and a dispersive part of surface energy. The polar part of surface energy and the dispersive part of surface energy of photoresist underlayer 306 can be calculated by measuring a contact angle of a liquid, such as water or CH₂I₂, and using the Owens, Wendt, Rabel and Kaelble (OWRK) method to determine the polar part and the dispersive part of the surface energy. The same properties can be measured and calculated for photoresist layer 308. A thickness of adhesion layer 310 can be greater than 0 nm and less than 2 nm. A thickness of the underlayer plus a thickness of the adhesion layer can be less than 10 nm, less than 5 nm, or less than 0.5 nm.

In accordance with various examples of the disclosure, a value of a polar part of surface energy of adhesion layer 310 is between about 7 mN/m to about 20 mN/m or about 4 mN/m to about 19 mN/m. In accordance with further examples, a value of a dispersive part of surface energy of adhesion layer 310 is between about 32 mN/m to about 37 mN/m, or about 32 mN/m to about 42 mN/m. For example, when photoresist layer 308 includes positive tone CAR photoresist, a value of the polar part of surface energy of the photoresist underlayer can be between about 3 mN/m to about 9 mN/m and/or a value of the dispersive part of surface energy of the photoresist underlayer can be between about 26 mN/m to about 32 mN/m.

By way of examples, with the utilization of an oxygen-free plasma to form adhesion layer 310, dangling bonds potentially behave as the surface reactive sites and lead to the chemisorption when the silicon precursor is introduced onto the film. Hence, ligands (e.g., CHx ligands) in the silicon precursor structure can eventually remain on the surface, which results in a desired surface free energy. The adhesive layer can be intrinsically SiOC, ending up with surface hydrocarbons.

In accordance with examples of the disclosure, process conditions, such as the process conditions noted above in table 1 can be manipulated to change a surface free energy of the adhesion layer to be within a desired range of the SFE of photoresist layer 308. By way of examples, the SFE of photoresist layer 308 can be ±10% or ±5% the SFE of the adhesion layer. additionally or alternatively, the polar part of the SFE of photoresist layer 308 can be ±10% or ±5% the polar part of the SFE of the adhesion layer. Additionally or alternatively, the dispersive part of the SFE of photoresist layer 308 can be ±10% or ±5% the dispersive part of the SFE of the adhesion layer.

Photoresist layer 308 can be or include positive or negative tone (e.g., EUV) photoresist.

Further described, now referring to FIG. 4, is a system 400 configured for executing a method as described herein. System 400 comprises at least one reaction chamber which is configured for depositing an underlayer and forming an adhesion layer as described herein. System 400 may comprise a first reaction chamber 411 and a second reaction chamber 412 that may both be configured for depositing an underlayer and forming an adhesion layer as described herein, or a part thereof. If desired, system 400 can include a third reaction chamber 413 in which another process, such as a thermal or plasma-enhanced post treatment may be carried out.

FIG. 5 illustrates an exemplary reactor system 500 (e.g., suitable for use as reaction chamber 411 or 412) in greater detail. Reactor system 500 can be used to perform one or more steps or sub steps as described herein and/or to form one or more structures or portions thereof as described herein.

Reactor system 500 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 13.56 MHz or 27 MHz) from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, and/or the like can be introduced into reaction chamber 3 using one or more of a gas line 20, a gas line 21, and a gas line 22, respectively, and through the shower plate 4. Although illustrated with three gas lines, reactor system 500 can include any suitable number of gas lines. Gas line 20 can be coupled to a silicon precursor source 29, gas line 21 can be coupled to an inert gas source 27, and gas line 22 can be coupled to another (e.g., reactant) gas source 28.

In reaction chamber 3, a circular duct 13 with an exhaust line 7 is provided, through which gas in the interior 11 of the reaction chamber 3 can be exhausted. Additionally, a transfer region 5, disposed below the reaction chamber 3, is provided with a seal gas line 24 to introduce seal gas into the interior 11 of the reaction chamber 3 via the interior 16 (transfer zone) of the transfer region 5, wherein a separation plate 14 for separating the reaction zone and the transfer zone is provided (a gate valve through which a wafer is transferred into or from the transfer region 5 is omitted from this figure). The transfer region is also provided with an exhaust line 6. In some embodiments, the deposition and treatment steps are performed in the same reaction space, so that two or more (e.g., all) of the (e.g., deposition and adhesion layer) steps can continuously be conducted without exposing the substrate to air or other oxygen-containing atmosphere.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching between the main line and the detour line, without substantially fluctuating pressure of the reaction chamber.

Reactor system 500 also includes one or more controller(s) 26 programmed or otherwise configured to cause one or more method steps as described herein to be conducted. Controller(s) 26 are communicated with the various power sources, heating systems, pumps, robotics and gas flow controllers, or valves of the reactor, as will be appreciated by the skilled artisan. By way of examples, controller 26 can be configured to control gas flow of a silicon precursor and an inert gas to form an adhesion layer on a photoresist underlayer. Additionally or alternatively, the controller can be configured to perform steps to form a photoresist underlayer as described herein.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

We claim:

1. A method of forming a structure comprising a photoresist underlayer, the method comprising the steps of:
providing a substrate within a reaction chamber;
forming an underlayer on a surface of the substrate;
selecting a photoresist to deposit onto the adhesion layer;
manipulating process conditions for use during the step of forming the adhesion layer to tune properties of the adhesion layer based on the selected photoresist; and
using a cyclical deposition process, forming an adhesion layer on the surface of the underlayer.

2. The method of claim 1, wherein the photoresist underlayer comprises one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

3. The method of claim 1, further comprising a step of forming a photoresist layer overlying and in contact with the adhesion layer, wherein the photoresist layer comprises extreme ultraviolet (EUV) lithography photoresist.

4. The method of claim 1, comprising a step of forming a photoresist layer overlying and in contact with the adhesion layer, wherein the photoresist layer comprises a chemically amplified resist.

5. The method of claim 1, wherein the step of forming the adhesion layer comprises:
providing a silicon precursor to the reaction chamber;
providing an oxygen-free reactant into the reaction chamber; and
forming a plasma using the oxygen-free reactant to form activated species that react with the silicon precursor or a derivative thereof to form the adhesion layer.

6. The method of claim 1, wherein the step of forming the adhesion layer does not comprise providing a reactant comprising oxygen.

7. The method of claim 5, wherein the oxygen-free reactant comprises one or more of argon, helium, neon, krypton, xenon and hydrogen.

8. The method of claim 5, wherein the oxygen-free reactant is provided continuously during one or more cycles of the cyclical deposition process.

9. The method of claim 5, wherein the oxygen-free reactant is provided continuously during the step of forming the underlayer and one or more cycles of the cyclical deposition process.

10. The method of claim 1, wherein the process conditions are selected from one or more of reaction chamber temperature, reaction chamber pressure, gap between electrodes, precursor flowrate, reactant flowrate, precursor dilution, reactant dilution, precursor purge time, number of deposition cycles plasma power, and plasma power pulse time.

11. The method of claim 5, wherein the step of forming the underlayer comprises providing the silicon precursor.

12. The method of claim 5, wherein the silicon precursor comprises a molecule comprising a backbone structure selected from the group consisting of:

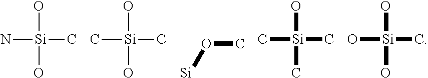

13. The method of claim 5, wherein the silicon precursor is represented by the formula: SiₐC_{b}O_{c}H_{d}Nₑ, where a is an integer from at least 0 to at most 5, b is an integer from at least 0 to at most 14, c is an integer from at least 0 to at most 4, d is an integer from at least 0 to at most 30, and e is an integer from at least 0 to at most 4.

14. The method of claim 5, wherein the silicon precursor comprises two silicon-oxygen bonds and two silicon-carbon bonds.

15. The method of claim 5, wherein the silicon precursor comprises a carbon-carbon double bond.

16. The method of claim 5, wherein the silicon precursor comprises one or more of N-[dimethoxy(propan-2-yl)silyl]-N-methylmethanamine, N-[ethyl(dimethoxy)silyl]-N-methylmethanamine, diisobutyldimethoxysilane, dimethoxydiethylsilane, dimethoxymethylvinylsilane, bis(methyldimethoxysilyl)methane, 1,2-bis(methyldiethoxysilyl)ethane, and trimethoxy(3-methoxypropyl)silane, methyltrimethoxysilane, tetramethylcyclotetrasiloxane, polymethysilsesquioxane, diethoxy-methyl-silane, dimethyl-dioxiranyl-silane, diethoxy-methyl-oxiranyl-silane, trimethyl-trivinylcyclotrisiloxane, decamethyl-cyclopentasiloxane and diethoxy-methyl-silane.

17. The method of claim 1, wherein the cyclical deposition process comprises a plasma-enhanced deposition process.

18. The method of claim 5, wherein the silicon precursor does not comprise nitrogen.

19. The method of claim 1, wherein a thickness of the adhesion layer is greater than 0 nm and less than 2 nm.

20. A structure formed according to the method of claim 1.

21. A system for forming an adhesion layer, the system comprising:
a reaction chamber;
a silicon precursor source fluidly coupled to the reaction chamber;
an inert gas source fluidly coupled to the reaction chamber; and
a controller configured to perform the method according to claim 1.
